(19) United States
(12) Patent Application Publication
(10) Pub. No.: US 2009/0145633 A1
(43) Pub. Date: Jun. 11, 2009

(54) DIRECT ATTACH INTERCONNECT FOR CONNECTING PACKAGE AND PRINTED CIRCUIT BOARD

(75) Inventor: Ashur S. Bet-Shliemoun, San Jose, CA (US)

Correspondence Address: BROOKS KUSHMAN P.C. / SUN / STK, 1000 TOWN CENTER, TWENTY-SECOND FLOOR, SOUTHFIELD, MI, 48075-1238, US

(73) Assignee: SUN MICROSYSTEMS, INC., Santa Clara, CA (US)

(21) Appl. No.: 12/262,662

(22) Filed: Oct. 31, 2008

Related U.S. Application Data
(63) Continuation-in-part of application No. 11/950,592, filed on Dec. 5, 2007.

(51) Int. Cl. H05K 1/00

(52) U.S. Cl. 174/254

(57) ABSTRACT

A direct attach interconnect includes a housing and spring contacts. The housing has top and bottom sides lying in parallel planes defined by x and y axes. The spring contacts are individually disposed within a passage in the housing such that a top end of the spring contacts extends out through the top housing side and a bottom end of the spring contacts extend out through the bottom housing side. The middle portion of each spring contact includes a connector which movably connects the middle portion of the spring contact to the passage for the spring contact such that the spring contact is movable along the x, y, and z axes. The bottom end of each spring contact includes a solder sphere and a solder pad. The top end of each spring contact is a land grid array or a pin rid array socket connector.

### CROSS-REFERENCE TO RELATED APPLICATIONS

This application is a continuation-in-part of U.S. application Ser. No. 11/950,592 filed Dec. 5, 2007.

### BACKGROUND OF THE INVENTION

1. Field of the Invention

The present invention relates to semiconductor packages that are directly attached on one end by soldering to a printed circuit board and that have sockets or spring contacts on an opposite end.

2. Background Art

A semiconductor package such as an integrated circuit requires mechanical and electrical connection with a printed circuit board (PCB). In the ball grid array (BGA) connection technique, one side of the package includes solder balls and one side of the PCB includes metal pads arranged in a pattern corresponding to the solder balls. The package is placed on the PCB such that the package and the PCB form an assembly with the corresponding solder balls and pads meeting. The assembly is heated causing the corresponding solder balls and pads to form solder joints thereby mechanically and electrically connecting the package and the PCB together. One problem with this approach is that the solder joints are not flexible and can fracture due to thermal stress caused by the difference in the coefficient of thermal expansion (CTE) between the package and the PCB. This problem may be overcome by using similar materials for the package and the PCB such that the package and the PCB have similar CTEs. However, this is costly and excessive thermal stresses can still be induced due to the thermal gradient.

The column grid array (CGA) connection technique somewhat solves the problem of different CTEs between a package and a PCB. In this technique, the solder balls are replaced with solder columns which have a lower stiffness and a higher standoff distance between the package and the PCB. Such features enable the columns to flex with less stress during dimensional expansion between the package and the PCB. However, some stress associated with different CTEs remains.

The respective CTEs of a socket and a PCB may be mismatched and may compromise the integrity of the interconnects. To minimize this problem, sockets and PCBs that have similar CTEs are specified. However, while this approach enhances reliability, thermal gradients between the package and PCB may induce thermal stresses that could reduce reliability.

### SUMMARY OF THE INVENTION

An object of the present invention includes a direct attach interconnect for mechanically and electrically connecting a semiconductor package and a printed circuit board (PCB) together to form an assembly in which the interconnect is between the package and the PCB and absorbs stresses associated with coefficient of thermal expansion (CTE) mismatches between the package and the PCB during temperature cycling and/or lifetime of the assembly.

Another object of the present invention includes a direct attach interconnect having a housing including movable spring contacts in which the housing is interposed between a package and a PCB and the spring contacts mechanically and electrically connect the package and the PCB.

A further object of the present invention includes a direct attach interconnect having a liquid crystal polymer (LCP) housing including movable spring contacts in which the housing is interposed between a package and a PCB and the spring contacts mechanically and electrically connect the package and the PCB.

Another object of the present invention includes a direct attach interconnect having a housing including movable spring contacts in which the housing is interposed between a package and a PCB and the spring contacts mechanically and electrically connect the package and the PCB with the spring contacts including a metal such as a copper alloy like beryllium copper.

A further object of the present invention includes a direct attach interconnect having a housing including movable spring contacts in which the housing is interposed between a package and a PCB and the spring contacts mechanically and electrically connect the package to the PCB with the spring contacts being movable in x, y, and z directions prior to and after the connection.

Another object of the present invention includes a direct attach interconnect having a housing including movable spring contacts in which one end of each spring contact is soldered to the package via solder paste and/or a solder sphere and the other end of each spring contact being in socket form to mechanically and electrically connect the package to the PCB.

A further object of the present invention includes a direct attach interconnect having a housing including passages (i.e., cavities) extending through top and bottom sides of the housing and spring contacts individually disposed within and extending through the passages with one end of each spring contact being soldered to the package via solder paste and/or a solder sphere and the other end of each spring contact being a socket with the housing interposed between the package and the PCB in order to mechanically and electrically connect the package to the PCB in which each spring contact is movably held in its passage to be movable in x, y, and z directions prior to and after the connection.

In carrying out the above objects and other objects, the present invention provides a direct attach interconnect (i.e., a direct attach interposer). The interconnect includes a housing having planar top and bottom sides lying in parallel planes defined by x and y axes. The housing further has passages extending along the z axis between the top and bottom sides of the housing. The interconnect further includes spring contacts each having a middle portion, a top end, and a bottom end. Each spring contact is individually disposed within a respective one of the passages such that the top end of the spring contact extends out through the top side of the housing and the bottom end of the spring contact extends out through the bottom side of the housing. The middle portion of each spring contact includes a connector which connects the middle portion of the spring contact to the passage for the spring contact such that the spring contact is movable along the x, y, and z axes. The bottom end of each spring contact includes a solder sphere and a solder pad, while the top end includes a socket connector.

Standoffs may be on the top and bottom sides of the housing. The housing may be a liquid crystal polymer (LCP) housing or be of a different material. Each spring contact may include a metal such as a copper alloy like beryllium copper.

The middle portion of at least one spring contact may include a 90° twist such that the top and bottom ends of the spring contact are movable in the x, y, and z axes.

At least one spring contact may include an S-bend portion between the middle portion and the top end of the spring contact such that the top end of the spring contact is movable in the x, y, and z directions. At least one spring contact may include an S-bend portion between the middle portion and the bottom end of the spring contact such that the bottom end of the spring contact is movable in the x, y, and z directions. One end of the one spring contact may include an arm connected to the one of the solder sphere and the solder pad to be movable in the x, y, and z directions.

Further, in carrying out the above objects and other objects, the present invention provides an assembly having a semiconductor package, a printed circuit board (PCB), and a direct attach interconnect. The package has a bottom side with socket connectors arranged thereon in a pattern. The PCB has a top side with solder connectors arranged thereon in the pattern. The interconnect includes a housing having top and bottom sides lying in parallel planes defined by x and y axes. The housing is sandwiched between the package and the PCB such that the bottom package side faces the top housing side and the top PCB side faces the bottom housing side. The housing includes passages arranged in the pattern and extending along the z axis between the top and bottom housing sides. The interconnect further includes spring contacts each having a middle portion and top and bottom ends. The spring contacts are individually disposed within respective passages such that the top ends of the spring contacts extend out through the top housing side and the bottom ends of the spring contacts extend out through the bottom housing side. The middle portion of each spring contact includes a connector which movably connects the middle portion of the spring contact to the passage for the spring contact such that the spring contact is movable along the x, y, and z axes. The bottom end of each spring contact includes a solder connector. The top end of each spring contact includes a socket connector.

Corresponding pairs of the socket connectors of the package and the top ends of the spring contacts are connected together to be movable in the x, y, and z axes as a result of the spring contacts being movable in the x, y, and z axes to accommodate expansion between the package and the PCB. Similarly, corresponding pairs of the solder connectors of the PCB and the bottom ends of the spring contacts are soldered together to form solder joints which are movable in the x, y, and z axes as a result of the spring contacts being movable in the z axis to accommodate expansion between the package and the PCB.

The socket connection between the package and the spring contacts that are supported by the LCP housing may take various forms. In one embodiment, the package may have pins that are received in tubular receptacles provided on the spring contacts. In another embodiment, the package may have pads in an array that are contacted by land grid array (LGA) contact springs.

The middle portion of at least one spring contact may include a 90° twist such that the socket connection at the top end and solder joint formed at the bottom end of the spring contact are movable in the x, y, and z axes. At least one spring contact may include an S-bend portion between the middle portion and each end of the spring contact such that the ends of the spring contact are movable in the x, y, and z directions.

The above features, and other features and advantages of the present invention as readily apparent from the following detailed descriptions thereof when taken in connection with the accompanying drawings.

### BRIEF DESCRIPTION OF THE DRAWINGS

FIG. 1 illustrates a side view of a direct attach interconnect in accordance with a first embodiment of the present invention;

FIG. 2 illustrates a side view of a direct attach interconnect in accordance with a second embodiment of the present invention;

FIG. 3 illustrates a first embodiment of a spring contact of a direct attach interconnect in accordance with the present invention;

FIG. 4 illustrates a second embodiment of a spring contact of a direct attach interconnect in accordance with the present invention;

FIG. 5 illustrates a side view of a direct attach interconnect in accordance with a third embodiment of the present invention;

FIG. 6 illustrates an exploded perspective view of the third embodiment of the present invention;

FIG. 7 illustrates a side view of a direct attach interconnect in accordance with a fourth embodiment of the present invention; and

FIG. 8 illustrates an exploded perspective view of the fourth embodiment of the present invention.

### DETAILED DESCRIPTION OF THE PREFERRED EMBODIMENT(S)

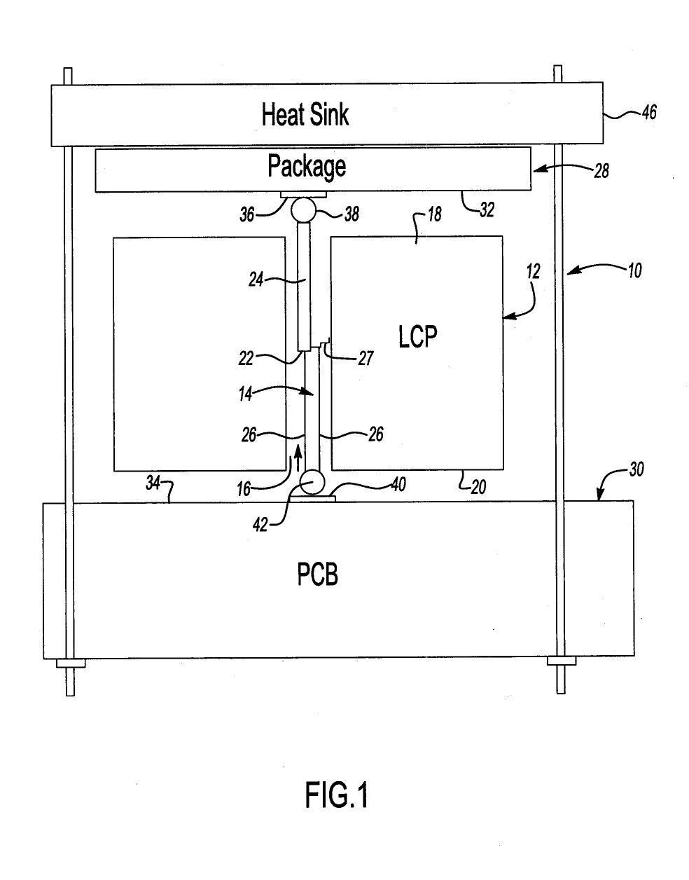

Referring now to FIG. 1, a side view of a direct attach interconnect 10 in accordance with a first embodiment of the present invention is shown. Interconnect 10 includes a liquid crystal polymer (LCP) housing 12 and a plurality of metal spring contacts 14 (only one spring contact being shown). Housing 12 includes a plurality of passages 16 (only one passage being shown) arranged in a pattern and extending through top and bottom sides 18, 20 of housing 12. Spring contacts 14 are individually disposed within and extend out of respective passages 16.

Each spring contact 14 includes a middle portion 22, a top end 24, and a bottom end 26. A connector 27 extends between middle portion 22 of a spring contact 14 and passage 16 for spring contact 14. Connector 27 movably connects middle portion 22 of spring contact 14 to passage 16 such that the spring contact may move in the z direction relative to its passage. Top end 24 of spring contact 14 extends out of passage 16 through top side 18 of housing 12. Bottom end 26 of spring contact 14 extends out of passage 16 through bottom side 20 of housing 12. As such, housing 12 holds spring contacts 14 in place in the pattern of passages 16.

Interconnect 10 is placed between a package 28 and a printed circuit board (PCB) 30 to mechanically and electrically connect the package and the PCB together and thereby form an assembly. To this end, package 28 and PCB 30 sandwich housing 12 with spring contacts 14 being soldered at one end to the package and soldered at the other end to the PCB in order for the package and the PCB to be mechanically and electrically connected together. Interconnect 10 absorbs stresses associated with coefficient of thermal expansion (CTE) mismatches between package 28 and PCB 30 (which are formed of two different materials) during temperature cycling and/or lifetime of the assembly. This is accomplished in part by providing spring contacts 14 that are able to float and move relative to housing 12 while being soldered to package 28 and PCB 30 in order to move with the expansion between the two different materials of the package and the PCB. That is, spring contacts 14 are held by housing 12 but are decoupled from the housing such that pressure/forces caused by expansion of package 28 and PCB 30 relative to one another minimizes stress on solder joints formed with the spring contacts as such pressure/forces are absorbed by the spring contacts themselves as they are movable in x, y, and z directions.

In general, interconnect 10 holds contact springs 14 in a desired array configuration. Interconnect 10 further absorbs compression forces between package 28 and PCB 30 to prevent such forces from damaging contact springs 14.

Housing 12 is placed between package 28 and PCB 30 with top side 18 of the housing facing a bottom side 32 of the package and bottom side 20 of the housing facing a top side 34 of the PCB. Bottom package side 32 includes a plurality of solder pads 36 (only one solder pad 36 being shown) arranged in the pattern corresponding to the pattern of spring contacts 14 such that each spring contact and each solder pad form a corresponding pair. Top end 24 of each spring contact 14 includes a solder ball 38. Solder balls 38 are to be soldered to the corresponding solder pads 36 to form mechanical and electrical connections between spring contacts 14 and package 28. Each soldered solder ball 38 and corresponding solder pad 36 form a solder joint between top end 24 of spring contact 14 and package 28. Similarly, top PCB side 34 includes a plurality of solder pads 40 (only one solder pad 40 being shown) also arranged in the pattern corresponding to the pattern of spring contacts 14 such that each spring contact and each solder pad 40 form a corresponding pair. Bottom end 26 of each spring contact 14 includes a solder ball 42. Solder balls 42 are to be soldered to the corresponding solder pads 40 to form mechanical and electrical connections between spring contacts 14 and package 30. Each soldered solder ball 42 and corresponding solder pad 40 form a solder joint between bottom end 26 of spring contact 14 and PCB 30.

Housing 12 may include features such as guide pins or the like on its top and bottom sides 18, 20 which are used to align the housing with package 28 and PCB 30.

The position of the corresponding solder pads and solder balls may be interchanged with respect to either of ends 24, 26 of spring contacts 14. For instance, top end 24 of a spring contact 14 may include a solder pad instead of solder ball 38, and a corresponding solder ball instead of the corresponding solder pad 36 may be placed on bottom package side 32. Likewise, bottom end 26 of a spring contact 14 may include a solder pad instead of solder ball 42, and a corresponding solder ball instead of the corresponding solder pad 40 may be placed on top PCB side 34. Further, any of the solder balls may be replaced with solder paste.

As described, spring contacts 14 are connected at their middle portions 22 within respective passages 16 of housing 12 by respective connectors 27. Connectors 27 provide minimal connection between spring contacts 14 and passages 16 such that the spring contacts are freely movable in the z direction either away from PCB 30 and toward package 28 or away from the package and toward the PCB. This assists to some extent in case of housing 12 being warped. Passages 16 have a large enough circumference such that spring contacts 14 do not come into contact with housing 12 along the side walls of the passages while moving in the x, y, and z axes during expansion between package 28 and PCB 30.

Further, each spring contact 14 itself has a resilient spring action such that top end 24 of the spring contact is movable in the z direction away from package 28 and toward PCB 30 while bottom end 26 of the spring contact is movable in the z direction away from the PCB and toward the package. Each spring contact 14 includes a metal such as a copper alloy like beryllium copper.

Spring contacts 14 are not connected at their top and bottom ends 24, 26 to passages 16 as the top and bottom spring contact ends respectively come into contact with package 28 and PCB 30 via solder and ultimately become solder joints. In conjunction, middle portion 22 of spring contacts 14 are movably connected to respective passages 16 of housing 12. As a result, housing 12 holds spring contacts 14 in their correct position (i.e., in the pattern corresponding to the patterns of the solder pads on bottom package side 32 and top PCB side 34. Further, the solder joints are decoupled from housing 12 and the associated stresses and CTE mismatches between package 28 and PCB 30.

FIG. 1 illustrates interconnect 10 between package 28 and PCB 30 just prior to the interconnect mechanically and electrically connecting the package and the PCB together to form an assembly. In order to form this assembly, package 28 is moved downward relative to housing 12 such that bottom package side 32 contacts top housing side 18. Likewise, PCB 30 is moved upward relative to housing 12 such that top PCB side 34 contacts bottom housing side 20. As a result, package 28 and PCB 30 sandwich housing 12. Solder pads 36 of package 28 and solder balls 38 of top ends 24 of the corresponding spring contacts 14 are soldered together (e.g., via re-flow soldering) and solder pads 40 of PCB 30 and solder balls 42 of bottom ends 26 of the corresponding spring contacts are also soldered together to form the mechanically and electrically interconnected assembly. Housing 12 further functions to absorb compression forces between package 28 and PCB 30 when assembled together such that spring contacts 14 can still freely move in both z directions with each end of the spring contacts being movable in x-y directions in order to accommodate expansion between the package and the PCB.

Thermal expansion between package 28 and PCB 30 occurs as a result of electronic components of the package and the PCB generating heat. For instance, package 28 may be an integrated circuit which can generate heat fluxes of several hundred watts per square centimeter. Package 28 includes heat sink 46 on its top side. Heat sink 46 functions to disburse some of this heat and may include any of well known structures for removing heat from electronic components such as a cold plate, a finned sink, a heat pipe, etc.

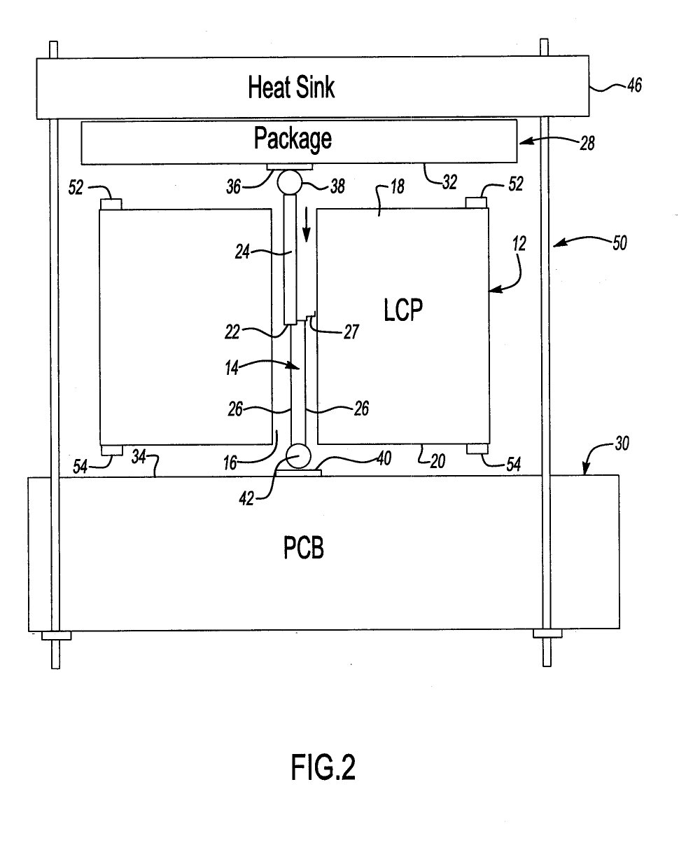

Referring now to FIG. 2, with continual reference to FIG. 1, a side view of a direct attach interconnect 50 in accordance with a second embodiment of the present invention is shown. Interconnect 50 includes the same elements as interconnect 10 and like elements have the same reference numerals. Interconnect 50 differs from interconnect 10 in that housing 12 of interconnect 50 includes a plurality of stoppers (or standoffs) 52, 54. A pair of stoppers 52 are arranged on top side 18 of housing 12 on respective sides of a passage 16 and a pair of stoppers 54 are arranged on bottom side 20 of housing 12 on respective sides of the passage. In contrast, top and bottom sides 18, 20 of housing 12 of interconnect 10 are flat. Stoppers 52, 54 provide clearance so that housing 12 does not come into contact with the solder joints formed between solder balls 38, 40 of spring contact 14 and the corresponding solder pads 36, 38 of package 28 and PCB 30. That is, stoppers 52, 54 are provided in case solder balls 38, 40 of a spring contact 14 are not able to fit within passage 16 of the spring contact as the solder joints are formed. As a result, bottom side 32 of package 28 is offset by the height of stoppers 52 from top side 18 of housing 12, and top side 34 of PCB 30 is offset by the height of stoppers 54 from bottom side 20 of housing 12 when the package and the PCB sandwich the housing.

Stoppers 52, 54 may be arranged in different areas of top housing side 18 and bottom housing side 20. For instance, stoppers can be placed on each corner and/or edge of housing sides 18, 20 and/or within the center of housing sides 18, 20, etc.

In the case of interconnect 10 which lacks such stoppers, passages 16 of housing 12 of interconnect 10 are large enough to receive solder balls 38, 40 of a spring contact as the solder joints are formed. Alternatively, solder pads 36, 40 of package 28 and PCB 30 are in recessed cavities and get pressed into their cavities as the solder joints are formed. In either event, bottom side 32 of package 28 is flush with top side 18 of housing 12, and top side 34 of PCB 30 is flush with bottom side 20 of housing 12 when the package and the PCB sandwich the housing.

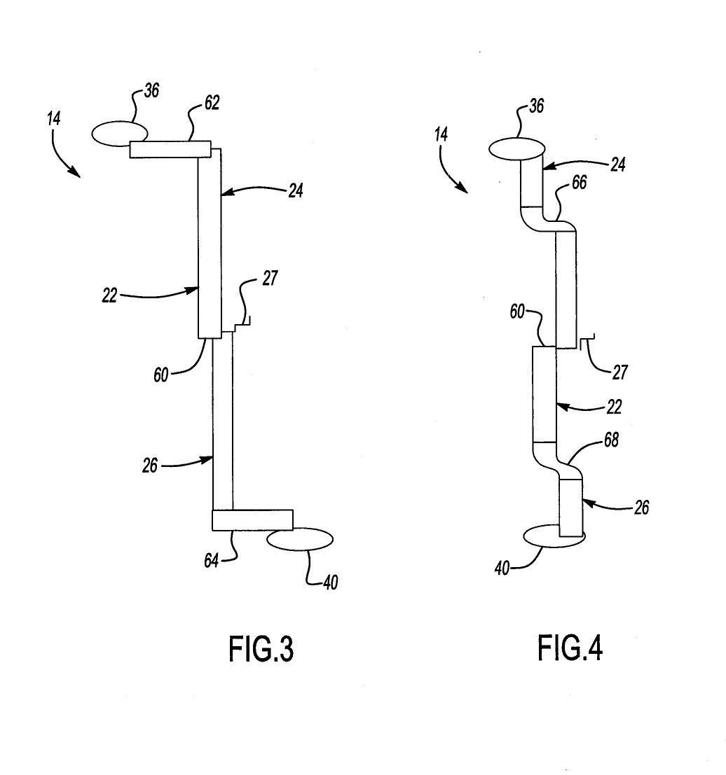

Spring contacts 14 can have various designs to allow x-y-z movement of the solder joints. FIG. 3 illustrates one such spring contact design. As shown in FIG. 3, spring contact 14 includes middle portion 22 and top and bottom ends 24, 26. Connector 27 is connected to middle portion 22 and is to be connected to passage 16 of spring contact 14 to provide minimal connection contact therebetween such that the spring contact is movable in the z direction. Middle portion 22 includes a 90° degree twist 60 which allows spring contact 14 to have free x-y motion. Top end 24 includes an arm 62 and a solder pad 36. Arm 62 accommodates free z-direction motion of top end 24. Likewise, bottom end 26 includes an arm 64 and a solder pad 40. Arm 64 accommodates free z-direction motion of bottom end 26. Arms 62, 64 are oriented in opposite directions from one another such that solder pads 36, 40 are offset from one another in the x-y direction. This accommodates x-ray inspection of spring contact 14. Alternatively, arms 62, 64 can be oriented in the same direction such that solder pads 36, 40 are aligned along the z-direction.

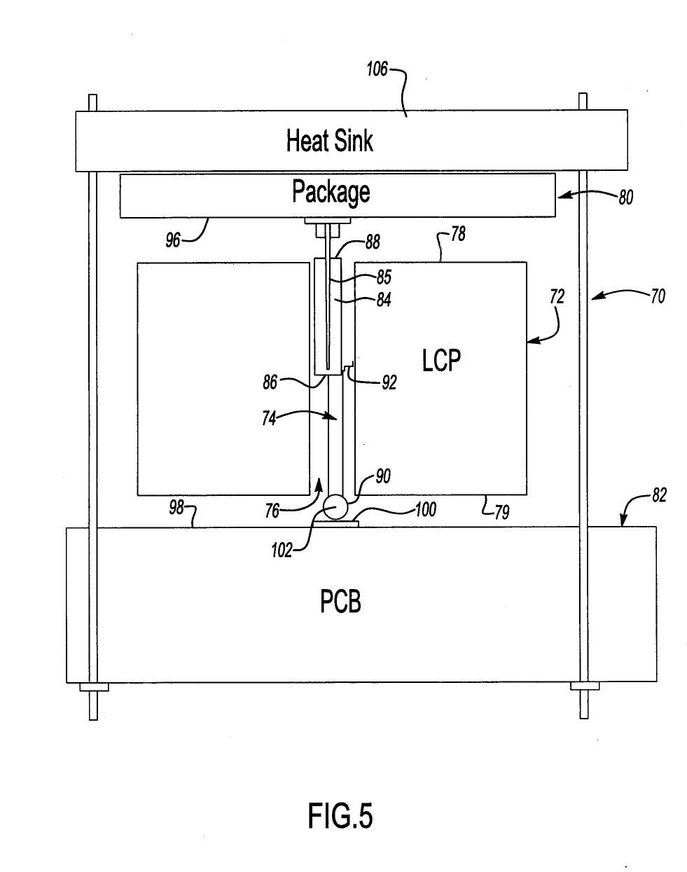

FIG. 4 illustrates another such spring contact design. Spring contact 14 includes middle portion 22 having twist 60, top end 24, and bottom end 26 with connector 28 connected to middle portion 22. Top end 24 includes a solder pad 36 at its top side. Bottom end 26 includes a solder pad 40 at its bottom side. Spring contact 14 further includes a top S-bend 66 between top end 24 and middle portion 22. S-bend 66 accommodates free z-direction motion of top end 24. Spring contact 14 further includes a bottom S-bend 68 between middle portion 22 and bottom end 26. S-bend 68 accommodates free z-direction motion of bottom end 26. S-bends 66, 68 are oriented in opposite directions from one another such that solder pads 36, 40 are offset from one another in the x-y direction. Alternatively, S-bends 66, 68 are oriented in the same direction such that solder pads 36, 40 are aligned along the z-direction. Either of S-bends 66, 68 may be Z-bends as well.

In a spring contact design in which the ends of the spring contact have a solder pad, the solder pad may have a “step” in order to allow more solder volume at the solder joint if desired. It is further noted that the solder balls associated with the spring contacts and/or the package and the PCB may be replaced with solder paste.

Referring now to FIG. 5, one embodiment of a direct attach interconnect for a pin grid array (PGA) 70 made in accordance with a third embodiment of the present invention is shown. Interconnect 70 includes a liquid crystal polymer (LCP) housing 72 and a plurality of metal spring contacts 74 (only one spring contact being shown). Housing 72 includes a plurality of passages 76 (only one passage being shown) arranged in a pattern and extending through top and bottom sides 78, 79 of housing 72. Spring contacts 74 are individually disposed within and extend out of their respective passages 76.

Interconnect 70 is placed between and mechanically and electrically connect a package 80 and a printed circuit board (PCB) 82. Spring contacts 74 have a tubular socket 84 on the end engaging the package 80 that receives a pin 85 of a PGA that extends from the package 80 and are soldered at the other end to the PCB 82. Interconnect 70 absorbs stresses associated with coefficient of thermal expansion (CTE) mismatches between package 80 and PCB 82 (which are generally formed of two different materials). Spring contacts 74 are able to float and move relative to housing 72 to accommodate different rates of expansion between the two different materials of the package 80 and the PCB 82. Spring contacts 74 are held by housing 72, but are decoupled from the housing 72 so that pressure/forces caused by expansion of package 80 and PCB 82 relative to one another minimizes stress on socket connectors 84 and solder joints formed on opposite ends of the spring contacts. The pressure/forces are absorbed by the spring contacts themselves as they are movable in x, y and z directions. Interconnect 70 holds contact springs 74 in an array and also absorbs compression forces between package 80 and PCB 82 to prevent such forces from damaging contact springs 74.

As explained previously with reference to FIGS. 1-4, each spring contact 74 includes a middle portion 86, a top end 88 and a bottom end 90. A housing connector 92 extends between middle portion 86 of a spring contact 74 and passage 76 for spring contact 74. Housing connector 72 movably connects middle portion 86 of spring contact 74 to passage 76 such that the spring contact may move in the z direction relative to its passage. Top end 88 of spring contact 74 extends out of passage 76 through top side 78 of housing 72. Bottom end 90 of spring contact 74 extends out of passage 76 through the bottom side 79 of housing 72. Housing 72 holds spring contacts 74 in place in the passages 76.

Housing 72 is placed between package 80 and PCB 82 with the top side 78 of the housing facing a bottom side 96 of the package 80 and bottom side 79 of the housing facing a top side 98 of the PCB 82. Bottom package side 96 includes a plurality of pins 85 (only one pin 85 being shown) arranged in the pattern corresponding to the pattern of sockets 84 such that each pin 85 and each socket connector 84 form a corresponding pair. The top end 88 of each spring contact 74 includes a pin 85, that is aligned with a socket 84. Top PCB side 98 includes a plurality of solder pads 100 (only one solder pad 100 being shown) arranged in the pattern corresponding to the pattern of spring contacts 74 such that each spring contact and each solder pad 100 form a corresponding pair. The bottom end 90 of each spring contact 74 includes a solder ball 102. Solder balls 102 are soldered to the corresponding solder pads 100 to form mechanical and electrical connections between spring contacts 74 and PCB 82. Each soldered ball 102 and corresponding solder pad 100 form a solder joint between bottom end 90 of spring contact 74 and PCB 82.

As described, spring contacts 74 are connected at their middle portions 86 within respective passages 76 of housing 72 by respective housing connectors 92. Connectors 92 provide minimal connection between spring contacts 74 and passages 76 such that the spring contacts are freely movable in the z direction either away from PCB 82 and toward package 80 or away from the package 80 and toward the PCB 82. Passages 76 have a large enough circumference such that spring contacts 74 do not come into contact with housing 72 along the side walls of the passages while moving in the x, y and z axes during expansion between package 80 and PCB 82.

Each spring contact 74 has a resilient spring action such that top end 88 of the spring contact is movable in the z direction away from package 80 and toward PCB 82, while bottom end 90 of the spring contact is movable in the z direction away from the PCB and toward the package. Each spring contact 74 may be formed, at least in part, from a copper alloy such as beryllium copper.

The middle portion 86 of spring contacts 74 are movably connected to respective passages 76 of housing 72. As a result, housing 72 holds spring contacts 74 in position (i.e., in the pattern corresponding to the patterns of the solder pads on bottom package side 96 and top PCB side 98). The socket connectors and solder joints are decoupled from housing 72 and the associated stresses and CTE mismatches between package 80 and PCB 82.

Thermal expansion between package 80 and PCB 82 occurs as a result of electronic components of the package and the PCB generating heat. For instance, package 80 may be an integrated circuit which can generate heat fluxes of several hundred watts per square centimeter. Package 80 includes heat sink 106 on one side. Heat sink 106 functions to disburse some of this heat and may include any of well known structures for removing heat from electronic components.

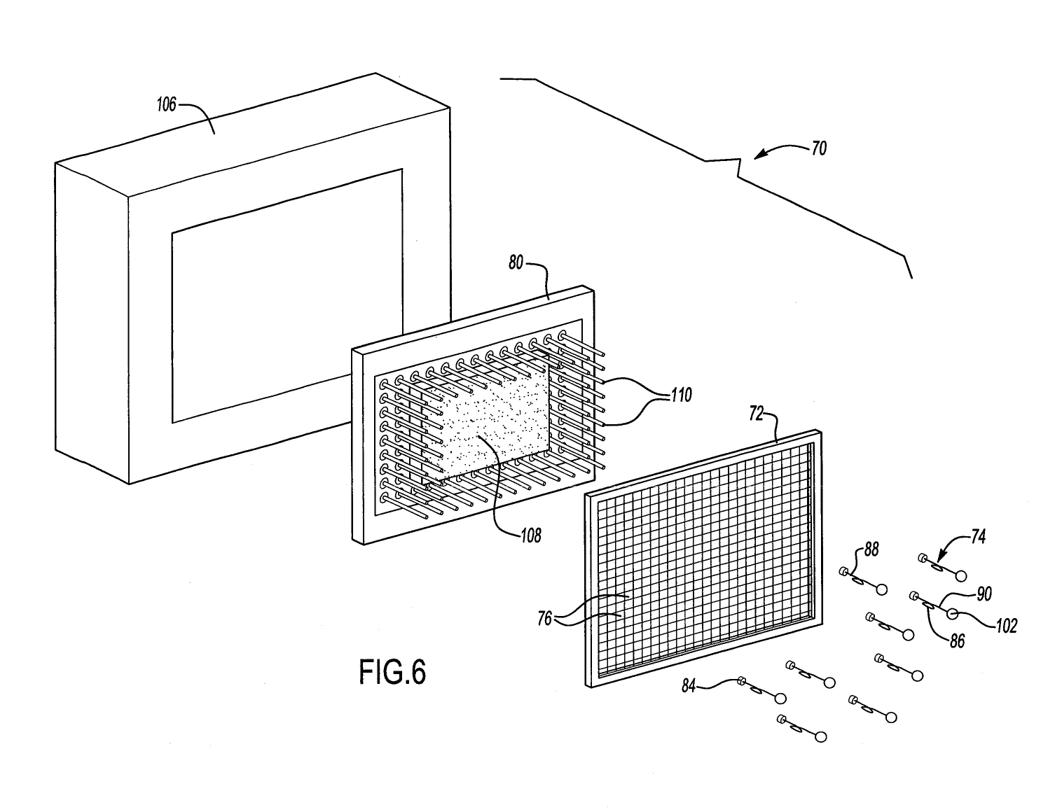

FIG. 6 illustrates the embodiment of interconnect 70 described with reference to FIG. 5 above. The interconnect 70 is shown in an exploded perspective view without the printed circuit board. Spring contacts 74 are shown separated from the passages 76 of the housing 72. The spring contacts 74 include a middle portion 86, an upper portion 88 and a lower portion 90. The central portion 86 of the spring contacts 74 may have various designs to allow x-y-z movement, as previously described with reference to FIGS. 3 and 4. The middle portion 86 may include a 90° twist as described with reference to FIG. 3 or may have an S-bend as described with reference to FIG. 4 above. Other possible shapes, such as Z-bends, may be incorporated in the central portion 86 of the spring contacts 74. The spring contacts include a socket connector 84 on their upper ends 88 that may be connected to the package 80. The package 80 may be a microprocessor 108 which includes a plurality of rigid pins 110 to which the socket connectors 84 are selectively attached when the package 80 is assembled to the spring contacts 74. The spring contacts 74 include solder balls 102 that are soldered to the solder pads 100, as previously described with reference to FIG. 5 above, to connect the spring contacts to the printed circuit board 82. The package 80 may be attached to a heat sink 106 to dissipate heat from the package 80.

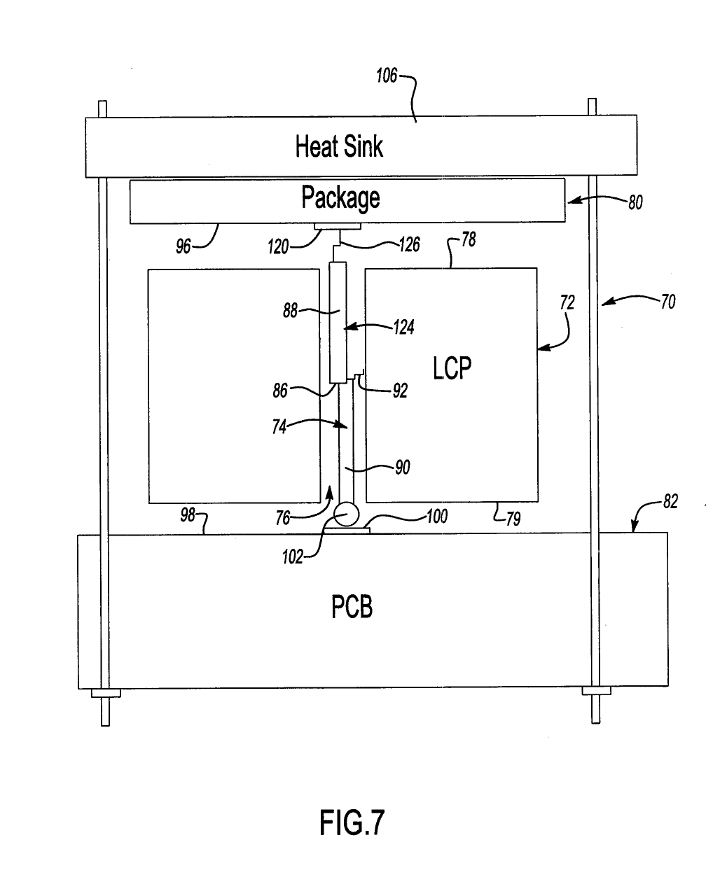

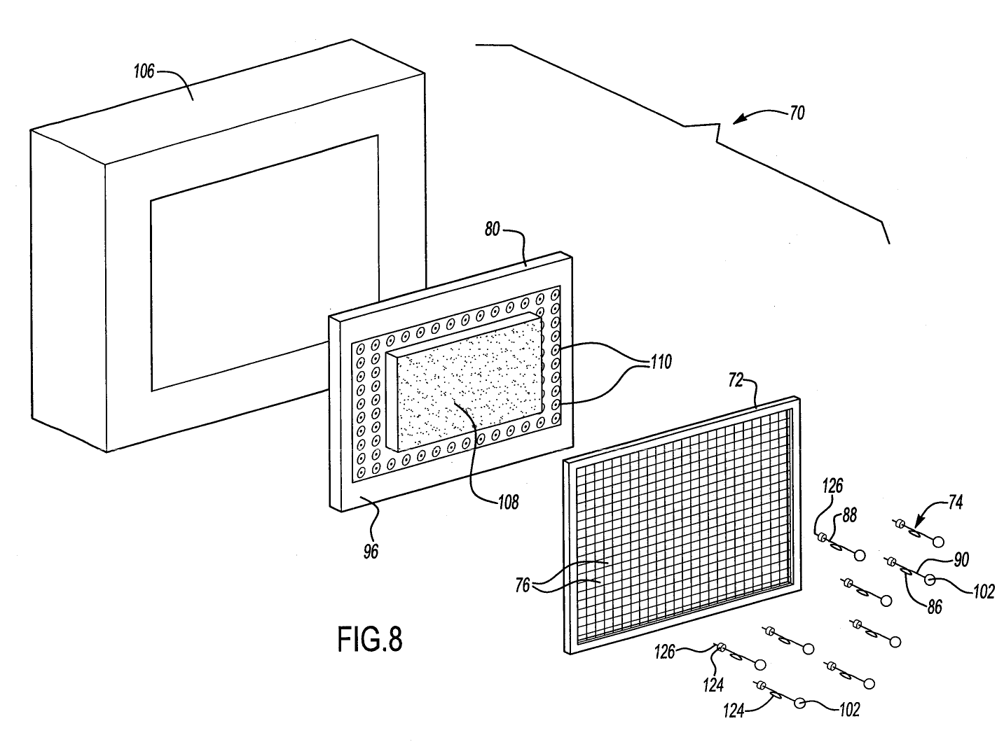

FIGS. 7 and 8 illustrate another embodiment of a direct connect interconnect 70 for a land grid array (LGA) that is similar in many respects to the embodiment shown in FIGS. 5 and 6. The same reference numerals will be used except for components that are different.

The description above with respect to FIGS. 5 and 6 is incorporated by reference for the embodiment of FIGS. 7 and 8. However, in this embodiment the package 80 is provided with a plurality of pads 120 on the bottom side 96. The spring pins 124 extending from the housing 72 have a spring contact 126 (diagrammatically represented) that is spring biased into engagement with the pads 120. The opposite end of the spring pins 124 are soldered by solder ball 102 to the solder pad 100, as previously described. The middle portion 86 of the spring pins 124 are connected by the housing connector 92 to the housing 72, as previously described.

While embodiments of the present invention have been illustrated and described, it is not intended that these embodiments illustrate and describe all possible forms of the present invention. Rather, the words used in the specification are words of description rather than limitation, and it is understood that various changes may be made without departing from the spirit and scope of the present invention.

What is claimed is:

1. A direct attach interconnect comprising:
a housing having planar top and bottom sides lying in parallel planes defined by x and y axes, the housing further having a plurality of passages extending along the z axis between the top and bottom sides of the housing; and
a plurality of spring contacts each having a middle portion, a top end, and a bottom end, each spring contact being individually disposed within a respective one of the passages such that the top end of the spring contact extends out through the top side of the housing and the bottom end of the spring contact extends out through the bottom side of the housing, wherein the middle portion of each spring contact includes a connector which connects the middle portion of the spring contact to the passage for the spring contact such that the spring contact is movable along the x, y, and z axes, wherein the bottom end of each spring contact includes a solder sphere and a solder pad, and wherein the top end of each spring contact includes a socket connector.

2. The interconnect of claim 1 wherein the socket connector further comprises a pin of a pin grid array that extends from a package and a receptacle is provided on each of the spring contacts that each receives one of the pins.

3. The interconnect of claim 1 wherein the socket connector further comprises a pad of a land grid array that is provided on a package and a contact is provided on each of the spring contacts that is spring biased into contact with one of the pads.

4. The interconnect of claim 1 wherein:
the middle portion of at least one spring contact includes a 90° twist such that the top and bottom ends of the spring contact are movable in the x, y, and z axes.

5. The interconnect of claim 1 wherein:
at least one spring contact includes an S-bend portion between the middle portion and the top end of the spring contact such that the top end of the spring contact is movable in the x, y, and z directions.

6. The interconnect of claim 1 wherein:
at least one spring contact includes an S-bend portion between the middle portion and the bottom end of the spring contact such that the bottom end of the spring contact is movable in the x, y, and z directions.

7. The interconnect of claim 6 wherein:
the at least one spring contact includes an S-bend portion between the middle portion and the top end of the spring contact such that the top end of the spring contact is movable in the x, y, and z directions.

8. An assembly comprising:
a semiconductor package having a bottom side with a plurality of socket connectors arranged thereon in a pattern;
a printed circuit board (PCB) having a top side with a plurality of solder connectors arranged thereon in the pattern; and
a direct attach interconnect including a housing having top and bottom sides lying in parallel planes defined by x and y axes, the housing sandwiched between the package and the PCB such that the bottom side of the package faces the top side of the housing and the top side of the PCB faces the bottom side of the housing, wherein the housing includes passages arranged in the pattern and extending along the z axis between the top and bottom sides of the housing;
the direct attach interconnect further including a plurality of spring contacts, each spring contact having a middle portion, a top end, and a bottom end, wherein each spring contact is individually disposed within a respective one of the passages such that the top end of the spring contact extends out through the top side of the housing and the bottom end of the spring contact extends out through the bottom side of the housing, wherein the middle portion of each spring contact includes a connector which movably connects the middle portion of the spring contact to the passage for the spring contact such that the spring contact is movable along the x, y, and z axes, wherein the bottom end of each spring contact includes a solder connector and wherein the top side of each spring contact includes a socket connector; and
wherein the socket connectors of the package and the top ends of the spring contacts are connected together to be movable in the z axis as a result of the spring contacts being movable in the z axis to accommodate expansion between the package and the PCB, and corresponding pairs of the solder connectors of the PCB and the bottom ends of the spring contacts are soldered together to form solder joints which are movable in the z axis as a result of the spring contacts being movable in the x, y, and z axes to accommodate expansion between the package and the PCB.

9. The assembly of claim 8 wherein:
the solder connectors of the PCB are solder pads and the solder connectors of the ends of the spring contacts are solder balls.

10. The assembly of claim 8 wherein:
the socket connectors comprise pin connectors that extend from the semiconductor package and receptacles that are provided on each of the pins that receive one of the pins.

11. The assembly of claim 8 wherein:
the socket connectors comprise pads provided on the semiconductor package and contacts provided on each of the pins that are spring biased into contact with one of the pads.

12. A system for connecting an electronic component package to a plurality of spring contacts, and to a printed circuit board, comprising:
inserting the spring contacts into a housing that defines a plurality of passages;
securing the pins to the housing with a connector that connects a middle portion of the pins to the housing while permitting the pins to move in any direction;
soldering a first end of each pin to a printed circuit board;
assembling the electronic component package to a second end of each pin, wherein the second end of each pin is attached to a first socket connector part and a second socket connector part is provided on the electronic component package.

13. The system of claim 12 wherein the second socket connector part is a pin grid array including a plurality of pin sockets and the system further comprises:
inserting the second end of each pin into one of the pin sockets.

14. The system of claim 13 further comprising:
biasing each pin into engagement with one of the pin sockets.

15. The system of claim 12 wherein the second socket connector part is a land grid array including a plurality of lands and the system further comprises:
assembling the second end of each pin into contact with one of the lands of the land grid array.

16. The system of claim 15 further comprising:
biasing each pin into engagement with one of the lands of the land grid array.

17. The system of claim 12 wherein:
moving the pins in an x direction, a y direction, and a z direction in response to changes in the thermal expansion of the package and the printed circuit board.
